(19) United States
(12) Patent Application Publication
(10) Pub. No.: US 2026/0219320 A1
(43) Pub. Date: Jul. 30, 2026

(54) ABNORMALITY DIAGNOSIS DEVICE AND ABNORMALITY DIAGNOSIS METHOD

(71) Applicant: Mitsubishi Electric Corporation, Tokyo (JP)

(72) Inventors: Hiroshi INOUE, Tokyo (JP); Makoto KANEMARU, Tokyo (JP); Ken HIRAKIDA, Tokyo (JP)

(73) Assignee: Mitsubishi Electric Corporation, Tokyo (JP)

(21) Appl. No.: 19/157,846

(22) PCT Filed: Apr. 18, 2023
(86) PCT No.: PCT/JP2023/015465

§ 371 Date: Aug. 19, 2025

(51) Int. Cl. G01R 31/34

(52) U.S. Cl. CPC G01R 31/34

(57) ABSTRACT

In an abnormality diagnosis device for determining abnormality of a load apparatus including an electric motor and load equipment connected to the electric motor, current of the electric motor is subjected to FFT analysis, the absolute values of differences between signal intensities for respective frequencies of a plurality of spectrum peaks extracted in diagnosis and signal intensities in a normal state are calculated, and the sum of the absolute values is used as a feature quantity, to determine abnormality.

### TECHNICAL FIELD

The present disclosure relates to an abnormality diagnosis device and an abnormality diagnosis method.

### BACKGROUND ART

A plant has a lot of load equipment connected to an electric motor via a motive power transmission mechanism, and abnormality diagnosis of the electric motor, the motive power transmission mechanism, and the load equipment is performed for maintenance.

In this regard, the following technology is known. With respect to an electric motor which is a drive source of a rotary machine system, sideband peaks related to abnormality of the rotary machine system are extracted from a spectrum pattern obtained through fast Fourier transform of a current signal during operation of the electric motor, and abnormality is detected from the intensity of the sideband peaks (see, for example, Patent Document 1).

### CITATION LIST

### Patent Document

Patent Document 1: Japanese Laid-Open Patent Publication No. 2017-181437

### SUMMARY OF THE INVENTION

### Problem to be Solved by the Invention

However, in the technology disclosed in Patent Document 1, the relationship between the intensities of the sideband peaks and whether or not there is abnormality changes depending on a load torque. Therefore, depending on selection of a frequency and a load torque of interest, diagnosis accuracy is reduced.

The present disclosure has been made to solve the above problem, and an object of the present disclosure is to provide an abnormality diagnosis device and an abnormality diagnosis method that can accurately perform abnormality diagnosis for a load apparatus including an electric motor such as a rotary machine system.

### Means to Solve the Problem

An abnormality diagnosis device according to the present disclosure is an abnormality diagnosis device for determining abnormality of a load apparatus including an electric motor and load equipment connected to the electric motor, the abnormality diagnosis device including: a current detector which detects current of the electric motor; and an abnormality diagnosis unit which performs FFT analysis on the current detected by the current detector and determines abnormality using extracted spectrum peaks. The abnormality diagnosis unit includes: a peak analysis unit which performs analysis using a power supply frequency of the electric motor and frequencies of sideband peaks with respect to the power supply frequency, and analyzes the extracted spectrum peaks for each frequency; a frequency determination unit which determines, from the spectrum peaks analyzed by the peak analysis unit, which kind of the electric motor and the load equipment the spectrum peak for each frequency is due to; a frequency storage unit which stores, for each load torque of the electric motor, the frequencies and signal intensities of the spectrum peaks due to the electric motor, and the frequencies and signal intensities of the spectrum peaks due to the load equipment, when the load apparatus is in a normal state; and an abnormality determination unit. The abnormality determination unit includes: a load torque selection unit which selects a load torque present when the current is detected by the current detector in abnormality diagnosis; a feature quantity calculation unit which, with respect to a plurality of diagnosis spectrum peaks for which the kind has been determined from FFT analysis on the current detected in the abnormality diagnosis, reads the frequencies and the signal intensities of the spectrum peaks in the normal state corresponding to the load torque selected by the load torque selection unit and the determined kind, from the frequency storage unit, and calculates, regarding the plurality of diagnosis spectrum peaks, absolute values of differences of signal intensities from those in the normal state for the respective frequencies, to use a sum of the absolute values as a feature quantity; and a feature quantity determination unit which compares a predetermined threshold and the feature quantity to determine abnormality of the load apparatus.

### Effect of the Invention

The abnormality diagnosis device and the abnormality diagnosis method according to the present disclosure make it possible to accurately perform abnormality diagnosis of a load apparatus including an electric motor.

### BRIEF DESCRIPTION OF THE DRAWINGS

FIG. 1 illustrates a schematic configuration of an abnormality diagnosis device according to embodiment 1.

FIG. 2 shows an example of a configuration of a control device for driving an electric motor according to embodiment 1.

FIG. 3 is a block diagram showing a configuration of an abnormality diagnosis unit according to embodiment 1.

FIG. 4 is a spectrum waveform showing an example of an analysis result based on current FFT when loosening of a belt has progressed under no load.

FIG. 5 shows a spectrum waveform which is an example of an analysis result based on current FFT when loosening of the belt has progressed under a rated load.

FIG. 6 is a flowchart showing the entire procedure for performing abnormality diagnosis using the abnormality diagnosis device according to embodiment 1.

FIG. 7 is a flowchart showing a procedure for calculating a feature quantity.

FIG. 8 shows a spectrum waveform which is an example of an analysis result based on current FFT when the belt has begun to loosen under no load.

FIG. 9 shows a spectrum waveform which is an example of an analysis result based on current FFT when the belt has begun to loosen under the rated load.

FIG. 10 illustrates effects of an abnormality diagnosis method according to embodiment 1, where FIG. 10A shows the relationship between a belt tension and a feature quantity under no load and FIG. 10B shows the relationship between a belt tension and a signal intensity of a belt rotation frequency (−1st order) as a comparative example.

FIG. 11 illustrates effects of the abnormality diagnosis method according to embodiment 1, where FIG. 11A shows the relationship between a belt tension and a feature quantity under the rated load and FIG. 11B shows the relationship between a belt tension and a signal intensity of a belt rotation frequency (−1st order) as a comparative example.

FIG. 12 illustrates a schematic configuration of an abnormality diagnosis device according to embodiment 2.

FIG. 13 shows an example of function fitting for a belt tension and a feature quantity.

FIG. 14 shows an example of a hardware configuration of the abnormality diagnosis device according to each of embodiments 1 and 2.

FIG. 15 shows another example of a hardware configuration of the abnormality diagnosis device according to each of embodiments 1 and 2.

### DESCRIPTION OF EMBODIMENTS

Hereinafter, embodiments will be described with reference to the drawings. In the drawings, the same reference characters denote the same or corresponding parts.

### Embodiment 1

Hereinafter, an abnormality diagnosis device for a rotary machine system according to embodiment 1 will be described with reference to the drawings.

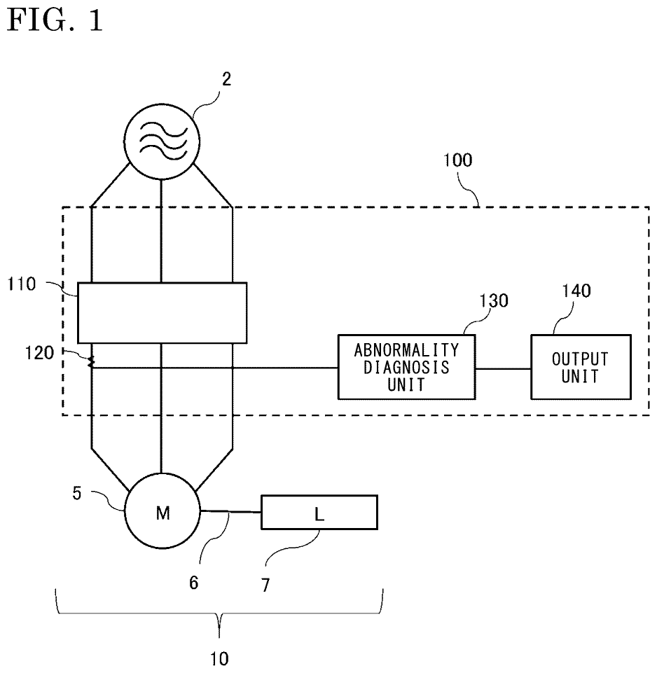

FIG. 1 illustrates a schematic configuration of an abnormality diagnosis device according to embodiment 1. An abnormality diagnosis device 100 detects abnormality of a load apparatus 10 and performs abnormality diagnosis. The load apparatus 10 includes an electric motor 5, a motive power transmission mechanism 6 which transmits motive power from the electric motor 5 to load equipment 7, and the load equipment 7. The abnormality diagnosis device 100 detects abnormality of the electric motor 5, abnormality of the motive power transmission mechanism 6, and abnormality of the load equipment 7, and performs abnormality diagnosis. In the drawing, the electric motor 5 is an example of many components used in a plant or the like, and is connected to a power supply line to a power supply 2 for electric motor driving via an electric motor control device 110.

### <Configuration of Abnormality Diagnosis Device 100>

The abnormality diagnosis device 100 includes the electric motor control device 110, an abnormality diagnosis unit 130, an output unit 140, and a current detector 120 connected to one of three-phase power supply lines connected to the electric motor 5. The abnormality diagnosis device 100 may be provided in a motor control center for managing many electric motors placed in a plant or the like, or may be a motor diagnosis device provided separately from the motor control center, for example. The electric motor control device 110 may be provided to the abnormality diagnosis device 100, or may be provided independently of the abnormality diagnosis device 100.

The current detector 120 is, for example, a clamp-type CT (Current Transformer), and may be provided for each phase of the three-phase power supply lines. It suffices that measurement is performed for one of the phases. The providing position of the current detector 120 is not limited as long as drive current of the electric motor 5 can be measured. This means that detection accuracy does not change depending on the measurement position. In the present embodiment, it is assumed that u-phase current is detected, as an example. In a case of successively performing acquisition of a current waveform and abnormality diagnosis, a memory is strained or a computation processing circuit is subjected to overload by abnormality diagnosis. If it is not assumed that abnormality abruptly occurs in target equipment, data may be acquired as appropriate at a diagnosis timing, without acquiring data at all times. In a steady state, current data may be acquired once per hour.

The output unit 140 displays a diagnosis result from the abnormality diagnosis unit 130 or outputs an audio or visual alarm on the basis of the diagnosis result, to provide a notification of abnormality of the electric motor and the motive power transmission mechanism. Further, in a case where monitoring is performed by a monitoring control device or the like for the entire plant and abnormal states are centralized, the output unit 140 transmits the diagnosis result, using a communication function.

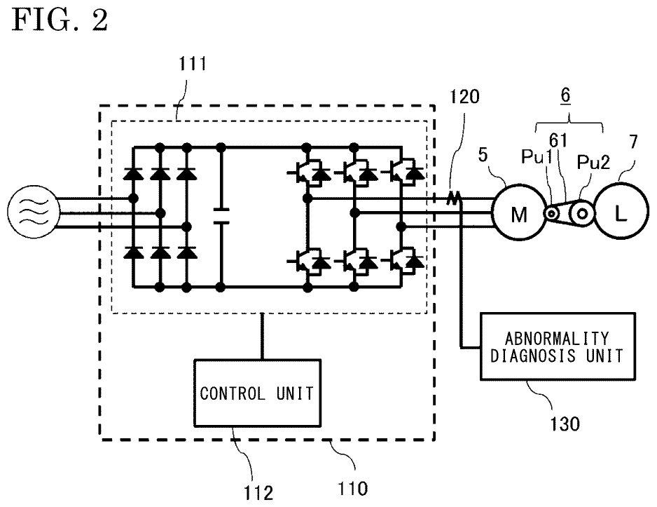

FIG. 2 illustrates a configuration of the electric motor control device 110. The electric motor control device 110 includes, for example, an inverter (power conversion device) 111 and a control unit 112 for driving the inverter 111. For example, in a case where the inverter 111 is composed of semiconductor switching elements, the semiconductor switching elements of the inverter 111 are drive-controlled so as to perform power conversion through PWM (Pulse Width Modulation) or the like using a carrier wave and a rectangular wave generated by the control unit 112. Here, the frequency of the carrier wave which is the base for driving the inverter 111 is a power supply frequency fₛ of the electric motor. The power converted by the inverter 111 is supplied to the electric motor 5. That is, the electric motor 5 is drive-controlled by the inverter 111.

The motive power transmission mechanism 6 is formed such that a motive power transmission member, e.g., a belt 61, is wound around an electric-motor-side pulley Pu1 connected to a rotary shaft of the electric motor 5 and a load-equipment-side pulley Pu2 connected to a drive shaft of the load equipment 7, for example.

As described above, the load apparatus 10 is composed of the electric motor 5, the motive power transmission mechanism 6, and the load equipment 7, but instead, the load apparatus 10 may be composed of the electric motor 5 and the load equipment 7 without including the motive power transmission mechanism.

The electric motor 5, the motive power transmission mechanism 6, and the load equipment 7 are not limited to specific types, in the present embodiment. For example, the electric motor may be an induction motor or a synchronous motor for a single phase or three phases, and the motive power transmission mechanism may be a belt, a gear, a coupling, or the like. The load equipment may be a pump, a fan, or the like. In a case of not providing the motive power transmission mechanism, the electric motor and the load equipment may be directly connected to each other.

### <Configuration of Abnormality Diagnosis Unit 130>

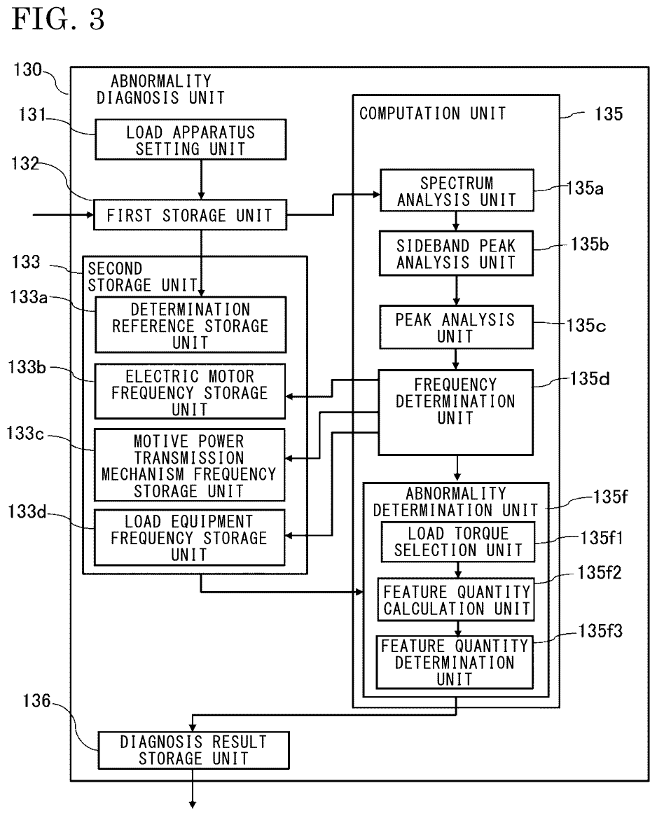

Next, a configuration of the abnormality diagnosis unit 130 will be described. FIG. 3 is a block diagram showing the configuration of the abnormality diagnosis unit 130 of the abnormality diagnosis device 100 according to embodiment 1. In FIG. 3, the abnormality diagnosis unit 130 includes a load apparatus setting unit 131, a first storage unit 132, a second storage unit 133, a computation unit 135, and a diagnosis result storage unit 136.

The load apparatus setting unit 131 is used for setting information about the electric motor 5, information about the motive power transmission mechanism 6, and information about the load equipment 7.

The load apparatus setting unit 131 is used for acquiring specifications of the electric motor 5 such as the power supply frequency, the number of poles, and the rated rotational speed from information of a rating plate attached to the electric motor 5. Using the above information, the rotation frequency of the electric motor 5 is accurately identified online in real time, and then is used for detecting mechanical abnormality of the electric motor.

In the load apparatus setting unit 131, in a case where the motive power transmission mechanism 6 is a belt, setting for recognizing that the belt is attached is performed. In a case where the motive power transmission mechanism 6 is absent, setting for recognizing the absence is performed.

In the load apparatus setting unit 131, setting according to the kind of the load equipment 7 is performed. For example, in a case of a fan, a condition of the rotational speed and the like of the fan is set.

The specifications information about the electric motor 5, the information about the motive power transmission mechanism, and the information about the load equipment 7 are stored in the first storage unit 132. The first storage unit 132 stores drive current of the electric motor 5 acquired by the current detector 120. In the present embodiment, the detected value of the u-phase current and the value of a load torque when the current is detected are stored together.

The second storage unit 133 includes a determination reference storage unit 133a, an electric motor frequency storage unit 133b, a motive power transmission mechanism frequency storage unit 133c, and a load equipment frequency storage unit 133d.

The determination reference storage unit 133a is used for storing thresholds for determining abnormality of the electric motor 5, abnormality of the motive power transmission mechanism 6, and abnormality of the load equipment 7, and the like.

The electric motor frequency storage unit 133b stores the values of frequencies of spectrum peaks due to the electric motor 5. It is preferable that not only the values of frequencies but also signal intensities of the spectrum peaks, the power supply frequency fₛ, a signal intensity of a spectrum peak for the power supply frequency, and a load torque of the electric motor 5, are stored. For all of these, results of analysis by the computation unit 135 described later are stored. In a case where arising frequencies have been found in advance, corresponding information may be acquired and set by the load apparatus setting unit 131. The load torque may be measured at the same time as current data of the electric motor 5 is acquired, or may be calculated by a known method using the acquired current waveform of the electric motor 5.

The motive power transmission mechanism frequency storage unit 133c stores the values of frequencies of spectrum peaks due to the motive power transmission mechanism 6. It is preferable that not only the values of the frequencies but also signal intensities of the spectrum peaks due to the motive power transmission mechanism 6, the power supply frequency fₛ when the spectrum peaks due to the motive power transmission mechanism 6 are acquired, the signal intensity of the spectrum peak for the power supply frequency, and the load torque of the electric motor 5, are stored.

The load equipment frequency storage unit 133d stores the values of frequencies of spectrum peaks due to the load equipment 7. It is preferable that not only the values of the frequencies but also signal intensities of the spectrum peaks due to the load equipment 7, the power supply frequency fₛ when the spectrum peaks due to the load equipment 7 are acquired, a signal intensity of the spectrum peak for the power supply frequency, and the load torque of the electric motor 5, are stored.

The computation unit 135 includes a spectrum analysis unit 135a, a sideband peak analysis unit 135b, a peak analysis unit 135c, a frequency determination unit 135d, and an abnormality determination unit 135f.

The spectrum analysis unit 135a executes current FFT (Fast Fourier Transform) analysis (frequency analysis), using current detected by the current detector 120.

The sideband peak analysis unit 135b detects all spectrum peaks from a spectrum waveform analyzed by the spectrum analysis unit 135a. It is preferable that the frequency range of detection is 0 to 1000 Hz. Next, the sideband peak analysis unit 135b determines spectrum peaks that satisfy a condition for sideband peaks among the detected spectrum peaks.

The peak analysis unit 135c analyzes the sideband peaks extracted by the sideband peak analysis unit 135b, for each frequency.

The frequency determination unit 135d determines whether the sideband peak is a spectrum peak due to the electric motor, a spectrum peak due to the motive power transmission mechanism, or a spectrum peak due to the load equipment, on the basis of a result of analysis by the peak analysis unit 135c. After the kind is determined for the frequency, the value of the frequency of the spectrum peak is stored in the corresponding frequency storage unit 133b, 133c, 133d of the second storage unit 133. It is preferable that, at the same time, the signal intensity of the spectrum peak, the operation frequency of the electric motor control device 110 when the spectrum peak is acquired, the signal intensity of the spectrum peak for the operation frequency, and the load torque of the electric motor 5 are also stored.

The abnormality determination unit 135f includes a load torque selection unit 135f1, a feature quantity calculation unit 135f2, and a feature quantity determination unit 135f3, and determines presence/absence of abnormality of the electric motor 5, abnormality of the motive power transmission mechanism 6, and abnormality of the load equipment 7.

The load torque selection unit 135f1 selects load torque of the electric motor 5 during operation or a load torque at which abnormality determination is performed.

The feature quantity calculation unit 135f2 calculates a feature quantity on the basis of the frequencies of the spectrum peaks corresponding to the selected load torque.

The feature quantity determination unit 135f3 compares the calculated feature quantity on the basis of a threshold stored in the determination reference storage unit 133a in advance, and determines presence/absence of abnormality.

The diagnosis result storage unit 136 stores a result of determination by the abnormality determination unit 135f and outputs the result to the output unit 140.

In the abnormality diagnosis device 100 according to embodiment 1, as an example, a case where the load equipment 7 is a fan, the motive power transmission mechanism 6 is the belt 61 shown in FIG. 2, and the electric motor 5 is a three-phase induction motor, will be described in detail. It is assumed that an abnormality target is tension abnormality of the belt of the motive power transmission mechanism 6. As the load apparatus 10 in which the belt is used as the motive power transmission mechanism 6 is driven for a long time, the tension of the belt is gradually reduced, so that the belt needs to be replaced at an appropriate timing. This example is chosen because automation for the replacement timing is increasingly required. Accordingly, analysis on the spectrum peaks, abnormality determination, and the like will also be described using tension abnormality of the belt of the motive power transmission mechanism 6 as an example.

### <Analysis on Spectrum Peaks in Computation Unit 135>

Next, an analysis method for the spectrum peaks in the computation unit 135 will be described. As described above, the spectrum analysis unit 135a executes current FFT analysis, using current of the electric motor 5 detected by the current detector 120. Regarding data of a current waveform to be used in current FFT analysis, the measurement time and the sampling frequency are set so that the data can be acquired with sufficient resolution up to a high-frequency region.

The measurement time relates to resolution, and the resolution only has to allow a peak of interest to be separated from adjacent peaks. Therefore, approximately 1 s or more is desirable. Meanwhile, the sampling frequency relates to the maximum value of frequencies. The feature quantity described later is the sum of signal intensities of high-order components. Therefore, in accordance with orders to be used, a high frequency region might be needed. In order to ensure this, a sampling frequency not smaller than two times the maximum frequency to be used in calculation is needed.

The spectrum waveform analyzed by the spectrum analysis unit 135a includes spectrum peaks due to the electric motor 5, the belt 61, and the fan which is the load equipment 7, composing the load apparatus 10. The spectrum waveform also includes noises due to the electric motor 5, the belt 61, and the fan which is the load equipment 7, composing the load apparatus 10. Therefore, it is desirable that a plurality of results of current FFT analysis are averaged. As an example, approximately five results may be averaged.

Next, the spectrum waveform analyzed by the spectrum analysis unit 135a will be described. First, a rotation frequency fₘ of the electric motor 5 is considered. Specifically, a provisional rotation frequency fₘ₀ when a slip s is set at 0 is calculated. The rotation frequency fₘ₀ is calculated as shown by the following Formula (1) using the power supply frequency fₛ and a number p of poles.

$${f}_{m 0} = {f}_{s} / p \qquad ( 1 )$$

Here, the actual rotation frequency fₘ is represented as shown by the following Formula (2) using the slip s.

$${f}_{m} = {f}_{s} ( 1 - s ) / p \qquad ( 2 )$$

From Formula (1) and Formula (2), the slip s is calculated as follows.

$$s = 1 - {f}_{m} / {f}_{m 0} \qquad ( 3 )$$

Here, the actual rotation frequency fₘ is a frequency at which a peak is a local maximum in the vicinity of the provisional rotation frequency fₘ₀ and near the power supply frequency fₛ. On the basis of this, the actual rotation frequency fₘ can be identified from the frequency analysis result. Using the actual rotation frequency fₘ and the provisional rotation frequency fₘ₀ calculated by Formula (1), the slip can be calculated. However, in this method, sufficient frequency resolution for calculating the slip is needed, and therefore the data acquisition time needs to be set to be long accordingly.

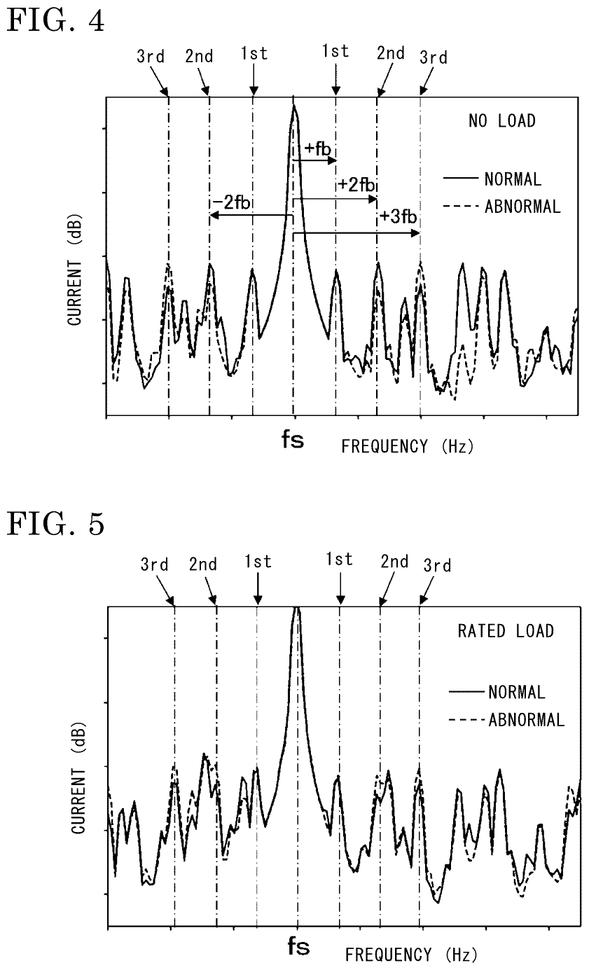

The sideband peak analysis unit 135b detects all spectrum peaks from the spectrum waveform analyzed by the spectrum analysis unit 135a. Regarding the spectrum waveform obtained through current FFT analysis, spectrum peaks that satisfy a condition of sideband peaks are determined with the power supply frequency fₛ at the center. FIG. 4 shows an example of a spectrum waveform based on current FFT of u-phase current of the electric motor 5 connected to the belt which is the motive power transmission mechanism 6, under no load torque of the electric motor 5. A great peak appears at the power supply frequency fₛ, and a plurality of sideband peaks are observed on both sides of the peak. Where the power supply frequency is fₛ, each rotation frequency is fᵢ, and the order of a harmonic is a natural number n, frequencies f of the sideband peaks are represented as shown by the following Formula (4).

$$f = {f}_{s} \pm n {f}_{i} \qquad ( 4 )$$

As described above, the spectrum peaks due to the electric motor 5, the belt 61, and the fan which is the load equipment 7, are included. The rotation frequency fₘ due to the electric motor 5 is represented by the above Formula (2). The rotation frequency fₗ due to the fan which is the load equipment 7 and the rotation frequency f_{b} due to the belt 61 which is the motive power transmission mechanism 6, are represented as shown by the following Formulae (5) and (6), respectively.

$${f}_{l} = {f}_{s} ( 1 - s ) / pr \qquad ( 5 )$$

$${f}_{b} = 2 π {r}_{m} {f}_{m} / {l}_{b} = 2 π {r}_{l} {f}_{l} / {l}_{b} \qquad ( 6 )$$

Where
r: speed reduction ratio
rₘ: diameter of electric-motor-side pulley Pu1
r₁: diameter of load-equipment-side pulley Pu2
l_{b}: length of belt

As described above, the rotation frequency fₘ due to the electric motor 5, the rotation frequency fₗ due to the fan, and the rotation frequency f_{b} due to the belt 61, can be calculated from the shapes and driving information about the electric motor 5, the fan, and the belt 61. The peak analysis unit 135c analyzes the sideband peaks extracted by the sideband peak analysis unit 135b, for each of the frequencies due to the respective parts.

In FIG. 4, sideband peaks for first to third orders of the rotation frequency f_{b} due to the belt 61 appear with the power supply frequency fₛ at the center, as described later in detail.

The frequency determination unit 135d determines the kinds as the rotation frequency fₘ due to the electric motor 5, the rotation frequency fₗ due to the fan, and the rotation frequency f_{b} due to the belt 61, and for each kind, frequencies for the first and higher orders in a normal state and the respective intensities thereof are stored into the second storage unit 133, together with the load torque with which the current used in current analysis has been acquired. For example, according to the analysis result in FIG. 4, from the spectrum in a normal state indicated by a solid line, frequencies of f=fₛ±nf_{b} (n is 1 to 3) as spectrum peaks due to the belt 61, signal intensities at the respective frequencies, and load torque 0 are acquired and stored into the motive power transmission mechanism frequency storage unit 133c.

FIG. 5 shows an example of a spectrum waveform based on current FFT of u-phase current of the electric motor 5 connected to the belt which is the motive power transmission mechanism 6, under the rated load of the electric motor 5. From the spectrum in a normal state indicated by a solid line in the analysis result shown in FIG. 5, frequencies of f=fₛ±nf_{b} (n is 1 to 3) as spectrum peaks due to the belt 61, signal intensities at the respective frequencies, and a load torque value (under rated load) are acquired and stored into the motive power transmission mechanism frequency storage unit 133c. Thus, in each frequency storage unit 133b, 133c, 133d, the frequencies of the corresponding spectrum peaks in a normal state, the signal intensities thereof, and the load torque value are stored.

In abnormality diagnosis, on the basis of the load torque when current is detected and subjected to FFT analysis, the load torque selection unit 135f1 of the abnormality determination unit 135f reads data such as the frequencies of the spectrum peaks corresponding to the load torque and the signal intensities for the respective frequencies, from the normal-state data stored in each frequency storage unit 133b, 133c, 133d of the second storage unit 133, into the abnormality determination unit 135f. Here, abnormality of the belt 61 is used as an example of an abnormality diagnosis target, and therefore the data is read from the motive power transmission mechanism frequency storage unit 133c.

Regarding the load torque, the load torque may be measured when current data is detected, and the measurement result may be stored. However, the load torque selection unit may select a load torque, using the current waveform. In the case of using the current waveform, a load torque need not be measured and a device for measuring a load torque is not needed, leading to cost reduction. In addition, since the state of a load torque need not be stored into a memory, there is an advantage that the memory capacity can be reduced.

In a selection method for a load torque using a current waveform, since the current amplitude increases as the load torque increases, the load torque is selected on a current amplitude basis. Instead of a current amplitude, any information that allows the magnitude of the current value to be found, e.g., the effective value of current, may be used to select the load torque. Alternatively, a method focusing on change in the rotation frequency along with change in the slip s as described above may be used. The slip s increases when the load torque increases. In Formula (2), the rotation frequency fₘ has s as a variable. Therefore, when the load torque increases, the rotation frequency fₘ also changes, so that the appearance location of the peak changes.

The feature quantity calculation unit 135f2 compares the frequencies and the signal intensities of the spectrum peaks for diagnosis obtained through analysis by the peak analysis unit 135c and determination by the frequency determination unit 135d, with the frequencies and the signal intensities of the spectrum peaks in a normal state corresponding to the selected load torque, read from the motive power transmission mechanism frequency storage unit 133c, and calculates a difference between the signal intensities for each frequency. For example, in FIG. 4 in which a solid line indicates a spectrum waveform in a normal state and a broken line (abnormal state) indicates a spectrum waveform at the time of abnormality diagnosis, a difference between the signal intensities is sequentially calculated for each of the frequencies of the spectrum peaks from the first order to a higher order (in FIG. 4, up to the third order), and the sum of the absolute values of the differences is calculated as a feature quantity C_{b}. If a spectrum waveform corresponding to the solid line in a normal state is obtained at the time of abnormality diagnosis, the feature quantity C_{b} is 0.

The feature quantity determination unit 135f3 determines whether or not the feature quantity C_{b} at the time of belt abnormality diagnosis calculated by the feature quantity calculation unit 135f2 is greater than a threshold Bₜₕ for belt abnormality diagnosis stored in the determination reference storage unit 133a, and if the feature quantity C_{b} is greater than the threshold Bₜₕ, the feature quantity determination unit 135f3 determines that there is abnormality.

The determination result of the feature quantity determination unit 135f3 is stored into the diagnosis result storage unit 136, and is outputted to the output unit 140.

### <Procedure of Abnormality Diagnosis Using Abnormality Diagnosis Device 100>

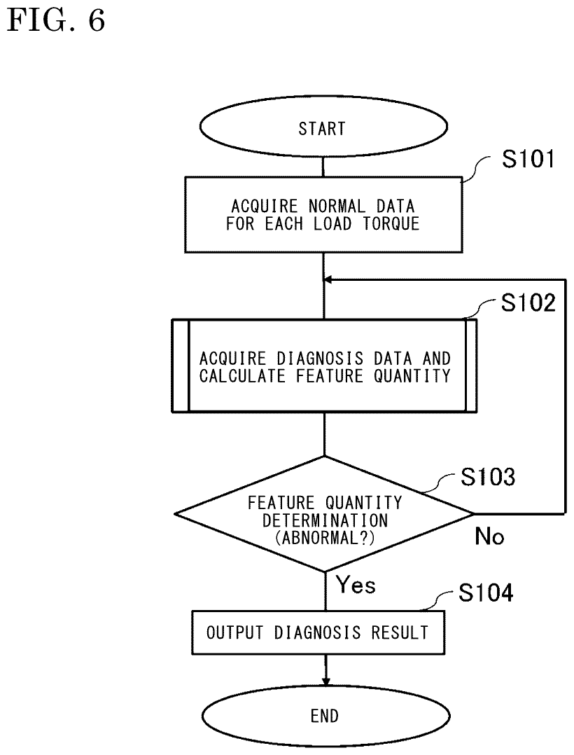

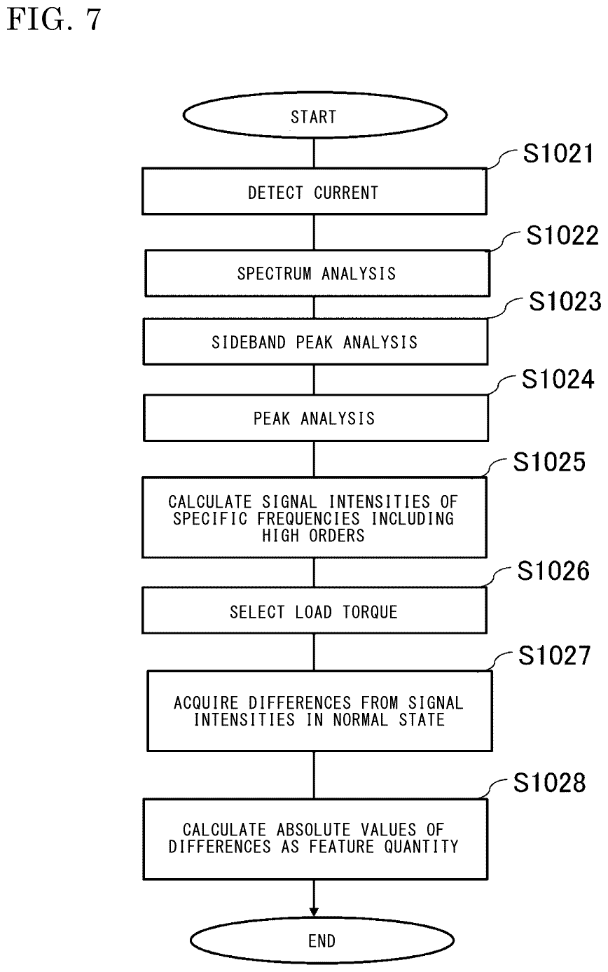

Next, operation of the abnormality diagnosis device 100 will be described with reference to FIG. 6 and FIG. 7. FIG. 6 is a flowchart showing the entire process for performing abnormality diagnosis using the abnormality diagnosis device 100 according to embodiment 1, and FIG. 7 is a flowchart showing a procedure for calculating the feature quantity.

First, the entire process of abnormality diagnosis will be described.

In step S101, data when a diagnosis target is in a normal state is acquired for each load torque. Specifically, as data when the tension of the belt 61 is in a normal state, u-phase current of the electric motor 5 is detected by the current detector 120 and the load torque is acquired together through measurement or calculation. The detected current is subjected to current FFT analysis by the spectrum analysis unit 135a as described above, and spectrum peaks are detected from the analyzed spectrum waveform by the sideband peak analysis unit 135b. The detected sideband peaks are analyzed for each frequency by the peak analysis unit 135c, and regarding the spectrum peaks due to the motive power transmission mechanism determined by the frequency determination unit 135d, the values of the frequencies of the spectrum peaks, the signal intensities thereof, and the load torque are stored into the motive power transmission mechanism frequency storage unit 133c.

The above process is the same as steps S1021 to S1025 in FIG. 7.

As an acquisition method for normal-state data, current just after the belt tension is renewed may be acquired and data obtained through analysis on the basis of the acquired current may be used as the normal-state data. Alternatively, normal-state data previously measured under the same condition may be stored. Since abnormality diagnosis is performed for each load torque, corresponding normal-state data also needs to be stored for each load torque.

If normal-state data has already been acquired, step S101 may be skipped.

Steps subsequent to step S102 are steps for performing abnormality diagnosis.

In step S102, as in step S101, u-phase current of the electric motor 5 is detected by the current detector 120 and is subjected to current FFT analysis, and a feature quantity is calculated.

In step S103, whether or not the calculated feature quantity is greater than a predetermined threshold, i.e., exhibits abnormality, is determined.

If it is determined that there is abnormality in step S103, the diagnosis result is outputted in step S104. If it is determined that there is no abnormality in step S103, abnormality diagnosis may be repeatedly performed with another load torque condition or the like.

Next, the details of the processing in step S102 will be described with reference to FIG. 7.

First, in step S1021, u-phase current of the electric motor 5 for abnormality diagnosis is detected by the current detector 120, and a load torque is acquired together through measurement or calculation. In regular diagnosis, the load torque may be selected in advance, and current when the electric motor 5 is operated with the predetermined load torque may be detected.

In step S1022, the detected current is subjected to current FFT analysis by the spectrum analysis unit 135a as described above.

In step S1023, the spectrum peaks are detected from the analyzed spectrum waveform by the sideband peak analysis unit 135b.

In step S1024, the detected sideband peaks are analyzed for each frequency by the peak analysis unit 135c.

In step S1025, the values of the frequencies and the signal intensities of the spectrum peaks due to the motive power transmission mechanism are calculated by the frequency determination unit 135d. At this time, the signal intensities of the spectrum peaks for up to the nth order set in advance are calculated. The values calculated here are relevant to spectrum peaks for diagnosis.

In step S1026, the load torque when current has been detected in step S1021 is selected by the load torque selection unit 135f1, and the values of the frequencies and the signal intensities of the spectrum peaks in a normal state corresponding to the selected load torque are read from the motive power transmission mechanism frequency storage unit 133c. At this time, the values of the frequencies and the signal intensities are read regarding the spectrum peaks for diagnosis for up to the nth order for which the signal intensities have been calculated in step S1025.

In step S1027, with respect to each of the spectrum peaks for diagnosis as an abnormality diagnosis target calculated in step S1025, the feature quantity calculation unit 135f2 calculates differences between the signal intensities thereof and the signal intensities of the spectrum peaks in a normal state read in step S1026. Next, in step S1028, the feature quantity calculation unit 135f2 sums the absolute values of the calculated differences between the signal intensities in diagnosis and in a normal state, for up to the nth order, and thus the sum is calculated as the feature quantity C_{b}.

### <Abnormality Determination Method>

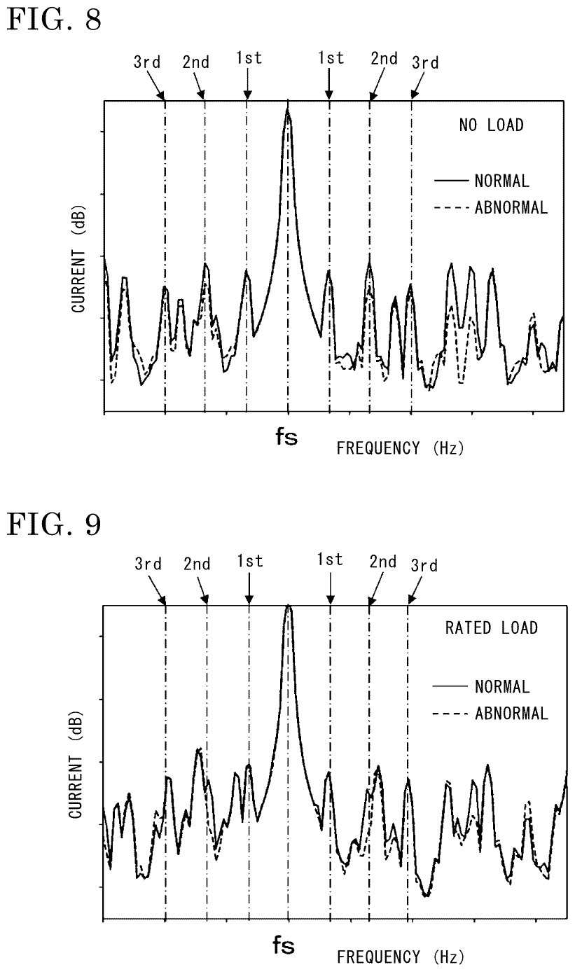

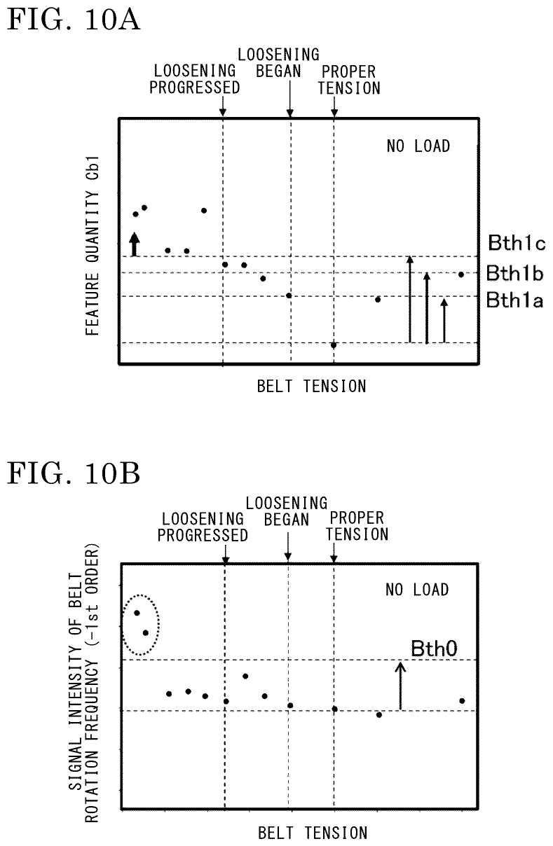

Next, the abnormality determination method according to the present embodiment and effects thereof will be described. The spectrum waveforms in an abnormal state indicated by the broken lines in FIG. 4 and FIG. 5 described above are examples in which loosening of the belt has progressed. Spectrum waveforms in an abnormal state indicated by broken lines in FIG. 8 and FIG. 9 are examples in which the belt has begun to loosen.

In a state in which loosening of the belt has progressed as shown in FIG. 4 and FIG. 5, under no load (load torque 0) in FIG. 4, the signal intensity of the second-order component of the rotation frequency f_{b} due to the belt 61 is reduced from the normal state, but the signal intensity of the third-order component is increased. Under the rated load (rated load torque) in FIG. 5, the second-order component exhibits almost no change but only the third-order component exhibits increase. From the above, it is considered that, when loosening of the tension has progressed, the third-order component of the rotation frequency f_{b} due to the belt 61 is an effective parameter for abnormality diagnosis.

In a state in which the belt has begun to loosen in FIG. 8 and FIG. 9, under no load (load torque 0) in FIG. 8, the signal intensity of the second-order component of the rotation frequency f_{b} due to the belt 61 is reduced from the normal state, but the third-order component exhibits no change. Therefore, the second-order component of the rotation frequency f_{b} due to the belt 61 is an effective parameter for abnormality diagnosis. However, under the rated load (rated load torque) in FIG. 9, components for the first, second, and third orders exhibit no great changes.

As described above, effective indices for abnormality diagnosis are different depending on the tension indicating the loosening state of the belt and the load torque. This is due to noises generated by devices such as the electric motor 5, the belt 61 which is the motive power transmission mechanism 6, and the fan which is the load equipment 7, and resonance among them. Therefore, in a case of selecting one feature frequency effective for abnormality diagnosis, abnormality diagnosis cannot be performed with high accuracy unless the frequency for an optimum order is selected in consideration of the above matters. In other words, in a case of performing abnormality diagnosis with only one feature frequency selected, there is a risk that high-accuracy diagnosis cannot be expected.

FIG. 10 illustrates effects of the abnormality diagnosis method according to embodiment 1. FIG. 10A shows the relationship between the belt tension and the feature quantity under no load, and FIG. 10B shows the relationship between the belt tension and the signal intensity (current value) for the belt rotation frequency for the −1st order, as a comparative example. In the graphs, a belt tension point indicated by “loosening began” corresponds to FIG. 8, and a belt tension point indicated by “loosening progressed” corresponds to FIG. 4.

In FIG. 10A, a feature quantity C_{b}1 under no load (load torque 0) calculated in the abnormality diagnosis device 100 according to the present embodiment 1 increases as the tension becomes away from a proper tension. That is, when loosening has begun, the feature quantity C_{b}1 begins to increase, and increases as loosening progresses. The proper tension corresponds to a normal state, and the feature quantity C_{b}1 in this state is 0 or almost 0. When the feature quantity C_{b}1 increases, the tension begins to shift from the proper tension, and when a predetermined threshold Bₜₕ1a is exceeded, it is determined that loosening has begun. When a threshold Bₜₕ1b is exceeded, for example, it is determined that “inspection is needed”. Further, when a threshold Bₜₕ1c is exceeded, it is determined that loosening has progressed and there is abnormality. Thus, in abnormality diagnosis, determination can be performed in accordance with loosening of the belt, i.e., the tension. The feature quantity C_{b}1 may be regularly calculated, whereby the belt tension at the time of the calculation can be recognized and occurrence of abnormality can be predicted. Thus, it is possible to perform maintenance before the load apparatus 10 stops due to belt breakage or the like.

FIG. 10B shows the relationship between the belt tension and the signal intensity for the belt rotation frequency for the −1st order in a case of using the belt rotation frequency for the −1st order as an index in abnormality diagnosis, as a comparative example. A region where the signal intensity greatly changes from the proper-tension state is a region indicated by an ellipse, and this region corresponds to a state in which a threshold Bₜₕ0 is exceeded and loosening of the belt has greatly progressed. In the comparative example, determination as abnormality is obtained when the region indicated by the ellipse is reached. That is, transition of loosening cannot be detected, unlike the present embodiment. The threshold Bₜₕ0 corresponds to the threshold Bₜₕ1a in FIG. 10A, and is, for example, 5 dB.

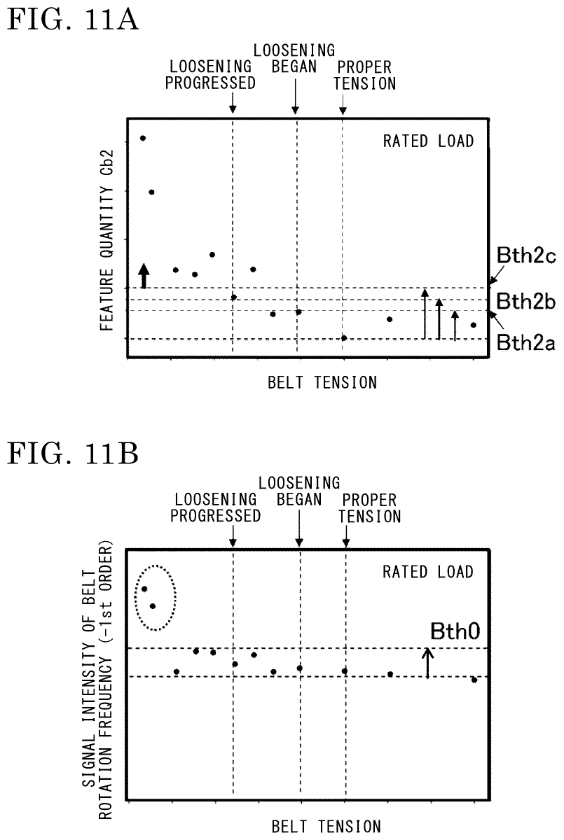

Similarly, FIG. 11 illustrates effects of the abnormality diagnosis method according to embodiment 1. FIG. 11A shows the relationship between the belt tension and the feature quantity under the rated load, and FIG. 11B shows the relationship between the belt tension and the signal intensity (current value) for the belt rotation frequency for the −1st order as a comparative example. In the graphs, a belt tension point indicated by “loosening began” corresponds to FIG. 9, and a belt tension point indicated by “loosening progressed” corresponds to FIG. 5.

Also in FIG. 11A, a feature quantity C_{b}2 under the rated load (rated load torque) calculated in the abnormality diagnosis device 100 according to the present embodiment 1 increases as the tension becomes away from the proper tension. That is, when loosening has begun, the feature quantity C_{b}2 begins to increase, and increases as loosening progresses. The proper tension corresponds to a normal state, and the feature quantity C_{b}2 in this state is 0 or almost 0. When the feature quantity C_{b}2 increases, the tension begins to shift from the proper tension. When a predetermined threshold Bₜₕ2a is exceeded, it is determined that loosening has begun. When a threshold Bₜₕ2b is exceeded, for example, it is determined that “inspection is needed”. Further, when a threshold Bₜₕ2c is exceeded, it is determined that loosening has progressed and there is abnormality. Thus, in abnormality diagnosis, determination can be performed in accordance with loosening of the belt, i.e., the tension. The feature quantity C_{b}2 may be regularly calculated, whereby the belt tension at the time of the calculation can be recognized and occurrence of abnormality can be predicted. Thus, it is possible to perform maintenance before the load apparatus 10 stops due to belt breakage or the like.

FIG. 11B shows the relationship between the belt tension and the signal intensity for the belt rotation frequency for the −1st order in a case of using the belt rotation frequency for the −1st order as an index in abnormality diagnosis, as a comparative example. As in the case of FIG. 10B, a region where the signal intensity greatly changes from the proper-tension state is a region indicated by an ellipse, and this region corresponds to a state in which a threshold Bₜₕ0 is exceeded and loosening of the belt has greatly progressed. In the comparative example, determination as abnormality is obtained when the region indicated by the ellipse is reached. That is, transition of loosening cannot be detected, unlike the present embodiment. The threshold Bₜₕ0 corresponds to the threshold Bₜₕ2a in FIG. 11A, and is, for example, 20 dB.

As described above, it is found that, in the case of performing abnormality diagnosis using the feature quantity which is the sum of the absolute values of differences between the signal intensities for the rotation frequency in diagnosis and the signal intensities for the rotation frequency in a normal state, diagnosis accuracy is higher as compared to the comparative example in which change in the intensity for a single rotation frequency is tracked.

The reason why the signal intensity for the rotation frequency changes in an abnormal state is that, when a rotor of the electric motor 5 vibrates, the gap between the rotor and a stator periodically changes, so that a magnetic flux density between the rotor and the stator changes. When the magnetic flux density changes, current changes, and this change is reflected in sideband peaks. When the belt 61 is loosened, there is a case where the above vibration greatly increases due to the loosening, or there is a case where torque transmission efficiency decreases due to the loosening, so that the vibration decreases. Thus, regarding increase or decrease in the signal intensity for the rotation frequency due to abnormality, both of the above cases can be assumed. However, in a case where abnormality has occurred or in a case of heading toward an abnormal state, the signal intensities change from those in a normal state.

Accordingly, the absolute values of differences corresponding to the changes are summed, up to a higher order, and the sum increases as the abnormality progresses. Therefore, using the feature quantity according to the present embodiment makes it possible to perform abnormality diagnosis with high accuracy.

In calculation of the feature quantity, differences of the signal intensities for the rotation frequency for the first to third orders between a normal state and an abnormal state are calculated in the above description. However, the present disclosure is not limited thereto. Components for up to an higher order may be selected as calculation targets, or only high-order components may be selected without selecting low-order components. The spectrum peaks for the rotation frequency as a target appear on the high-frequency side and the low-frequency side symmetrically with respect to the power supply frequency fₛ. In the above case, differences of the signal intensities of the peaks on both sides are summed. However, differences of the signal intensities on only one of the high-frequency side and the low-frequency side may be used to calculate a feature quantity.

In calculation of the feature quantity, the sum of the absolute values of differences of the signal intensities for the rotation frequency between a normal state and an abnormal state is used. However, the sum of differences of the signal intensities for the rotation frequency between a normal state and an abnormal state may be used. In this case, accuracy is expected to be deteriorated, but if the condition is adjusted, e.g., a plurality of specific peaks are used, it is possible to enhance diagnosis accuracy as compared to the comparative example in which change in the intensity for a single rotation frequency is tracked.

### <Setting of Thresholds to be Used for Abnormality Determination>

Next, a setting method for the thresholds will be described.

As described above, the feature quantity increases as loosening of the belt progresses. Therefore, by setting a threshold and determining that there is abnormality when the threshold is exceeded, abnormality diagnosis can be performed. As shown in FIG. 10A and FIG. 11A, if the relationship between the feature quantity and the belt tension has been found, the threshold can be determined accordingly. However, the feature quantity is not uniquely determined among various conditions. The sizes of devices of the load apparatus, e.g., the sizes of pulleys, the length of the belt, and the size of the fan, are not necessarily the same values, the drive condition can change, and a result can also differ depending on a condition such as how many orders of the rotation frequency should be taken as high-order components. Therefore, new setting may be often needed. Hereinafter, a setting method for thresholds without depending on conditions will be described.

One of threshold setting methods is a method in which signal intensities in a normal state are acquired a plurality of times and a standard deviation thereof is used. First, signal intensities in a normal state are calculated a plurality of times (q times). The frequency range in which the signal intensities are calculated is the frequency range for which the feature quantity is calculated. The signal intensities are calculated for the spectrum peaks for the frequencies for which the feature quantity is calculated. Here, the frequencies corresponding to loosening of the belt are targeted as described above. Regarding the signal intensity data for the plurality of times, the sum of the absolute values of differences between the signal intensities acquired at the first time and the signal intensities acquired at the second time for the frequencies corresponding to loosening of the belt is calculated. Similarly, the sums of the absolute values of differences between the signal intensities for the second to qth times are calculated. That is, data of the sums of the absolute values of differences between the signal intensities for the (q−1)th times are acquired. A standard deviation σ of the data of the sums of the absolute values of differences between the signal intensities for the (q−1)th times is calculated, and a value obtained by multiplying the standard deviation σ by a constant a is used as a threshold aσ. Therefore, in a case where the feature quantity has a value approximately corresponding to variation in the signal intensities in a normal state, it is not determined that there is abnormality. A plurality of constants may be set by sequentially increasing the constant a as a1, a2, . . . whereby a plurality of thresholds a1σ, a2σ, . . . can be set. As abnormality progresses, the feature quantity increases. Therefore, the abnormality level may be outputted in accordance with the value of the exceeded threshold, e.g., an abnormality level 1 for the threshold a1σ and an abnormality level 2 for the threshold a2σ.

The above frequency range in which the standard deviation σ is calculated, i.e., how many orders of the rotation frequency are used, may be determined in advance so as to match the later calculation of the feature quantity, and the standard deviation may be calculated in the corresponding range. The standard deviation may be calculated in a plurality of ranges.

When the signal intensities in a normal state are acquired a plurality of times, the signal intensities in a normal state for the plurality of times may be stored together with the standard deviation σ and the thresholds a1σ, a2σ, . . . into the determination reference storage unit 133a, or only the signal intensities of the spectrum for the first time may be stored. In calculating differences from signal intensities of a spectrum for diagnosis, the signal intensities of the spectrum for the first time may be used or the signal intensities of the spectrum for another time may be used.

Calculation of the feature quantity and abnormality determination are performed by the above methods. In a case of being diagnosed as abnormal, the diagnosis result is displayed on the output unit 140. As a display content, when the threshold is exceeded, only abnormality may be displayed, or in a case where a plurality of thresholds are set, an abnormality level may be displayed in accordance with the corresponding threshold. If the abnormality level is serious, the device may be stopped.

### <Examples Using Other Rotation Frequencies>

In the above description, while the load equipment 7 is the fan, the motive power transmission mechanism 6 is the belt 61, and the electric motor 5 is the three-phase induction motor, the tension of the belt 61 of the motive power transmission mechanism 6 is used as an abnormality diagnosis target. However, the abnormality diagnosis target may not necessarily be the belt 61.

The belt 61 exhibits a great radial load applied to the electric motor 5 due to belt connection. Therefore, the signal intensities for the rotation frequency including high-frequency components are great, and abnormality diagnosis can be favorably performed using, as an index, the feature quantity that is the sum of the absolute values of differences. Also for the electric motor 5 and the load equipment 7, since harmonic components of the rotation frequency arise, abnormality diagnosis can be performed in the same manner.

For example, on the basis of spectrum peaks and signal intensities of sideband peaks for f=fₛ+nfₘ using the rotation frequency fₘ of the electric motor 5, the sum of the absolute values of differences of the signal intensities of harmonics for up to the nth order between a normal state and an abnormal state of the electric motor 5 may be used as a feature quantity to perform abnormality determination.

Also in a case of the load equipment 7 which is not limited to the fan, on the basis of spectrum peaks and signal intensities of sideband peaks for f=fₛ+nfₗ using the rotation frequency fₗ of the load equipment 7, the sum of the absolute values of differences of the signal intensities of harmonics for up to the nth order between a normal state and an abnormal state of the electric motor 5 may be used as a feature quantity to perform abnormality determination.

Also in a configuration of the load apparatus 10 in which the electric motor 5 and the load equipment 7 are directly connected to each other without using the motive power transmission mechanism 6 such as the belt 61, abnormality diagnosis can be performed for the electric motor 5 and the load equipment 7.

While the example in which the belt 61 is an abnormality diagnosis target has been described, it should be understood that the electric motor 5, the motive power transmission mechanism 6, and the load equipment 7 may be subjected to abnormality diagnosis at the same time by determining spectrum peaks due to each of these devices in abnormality diagnosis.

As described above, according to embodiment 1, the abnormality diagnosis device 100 for determining abnormality of the load apparatus 10 includes: the current detector 120 which detects current of the electric motor 5; and the abnormality diagnosis unit 130 which performs FFT analysis on the detected current and determines abnormality using extracted spectrum peaks. The abnormality diagnosis unit 130 includes: the peak analysis unit 135c which performs analysis using a power supply frequency of the electric motor 5 and frequencies of sideband peaks with respect to the power supply frequency and analyzes a plurality of the extracted spectrum peaks for each frequency; the frequency determination unit 135d which determines, from the spectrum peaks analyzed for each frequency, which kind of the electric motor 5, the motive power transmission mechanism 6, and the load equipment 7 of the load apparatus 10 the spectrum peaks for each frequency are due to; the electric motor frequency storage unit 133b, the motive power transmission mechanism frequency storage unit 133c, and the load equipment frequency storage unit 133d which each store the frequencies and the signal intensities of the spectrum peaks due to the corresponding one of the kinds included in the load apparatus 10 when the load apparatus 10 is in a normal state; and the abnormality determination unit 135f. The abnormality determination unit 135f includes: the load torque selection unit 135f1 which selects the load torque present when the current detector 120 has detected the current in abnormality diagnosis; the feature quantity calculation unit 135f2 which, with respect to a plurality of diagnosis spectrum peaks for which the kind has been determined from FFT analysis of current detected in abnormality diagnosis, reads the frequencies and the signal intensities of the spectrum peaks in the normal state corresponding to the load torque selected by the load torque selection unit and the determined kind, from the frequency storage unit, and calculates, regarding the plurality of diagnosis spectrum peaks, the absolute values of differences of the signal intensities from those in the normal state for the respective frequencies, to use the sum of the absolute values as a feature quantity; and the feature quantity determination unit 135f3 which compares the predetermined threshold and the feature quantity to determine abnormality of the load apparatus 10. In this configuration, without performing determination by change in the signal intensity of one spectrum peak, abnormality is determined from the sum of the absolute values of differences from the normal state for a plurality of spectrum peaks, whereby high-accuracy abnormality diagnosis can be performed.

In the abnormality diagnosis device 100, in a case where time-series data of detected currents and analysis results are all stored, a large-capacity memory is needed. In the present embodiment, diagnosis is performed using only the signal intensities for the power supply frequency, the rotation frequency of the electric motor, the rotation frequency of the motive power transmission mechanism, and the rotation frequency of the load equipment. Thus, since only the signal intensities for specific frequencies are stored, a necessary memory can be reduced.

### Embodiment 2

Hereinafter, an abnormality diagnosis device 100 according to embodiment 2 will be described with reference to the drawings.

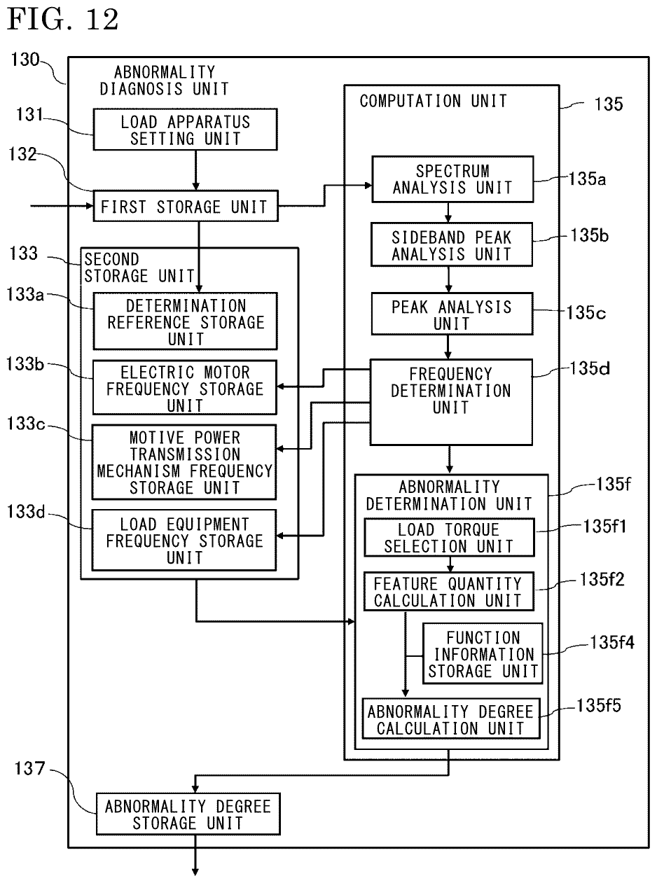

FIG. 12 is a block diagram showing a configuration of the abnormality diagnosis unit 130 of the abnormality diagnosis device 100 according to embodiment 2. Difference from FIG. 3 in embodiment 1 is that the abnormality determination unit 135f includes a function information storage unit 135f4 and an abnormality degree calculation unit 135f5, and the abnormality diagnosis unit 130 includes an abnormality degree storage unit 137 which stores and outputs an abnormality degree calculated by the abnormality degree calculation unit 135f5. In the present embodiment 2, the abnormality degree is quantitatively evaluated from the calculated feature quantity. As in embodiment 1, tension abnormality of the belt is targeted. As shown in FIG. 10A and FIG. 11A, the feature quantity tends to increase as loosening of the belt progresses. By performing function fitting for the relationship between the feature quantity and the abnormality degree, the relationship between the feature quantity and loosening of the belt is created, thus enabling quantitative evaluation. In the following description, the difference will be mainly described and description of the same matters as in embodiment 1 is omitted. Here, the abnormality degree can quantitatively represent the degree of progression from a normal state to an abnormal state.

In FIG. 12, the function information storage unit 135f4 stores information about a function fitted to the abnormality degree and the feature quantity, and the abnormality degree calculation unit 135f5 calculates the abnormality degree on the basis of the fitted function.

The function information needs to be created in advance, and in addition, the function information can change depending on specifications of each device of the rotary machine system, e.g., the belt length and the pulley diameter, and therefore, needs to be acquired for each equipment. Although there is a method of acquiring data in advance by providing test equipment using the same device, a method of acquiring data accumulated during driving of the electric motor may be used.

For example, when the feature quantity has increased and the belt should be replaced, the tension is measured, and the relationship between the feature quantity and the tension is stored in a memory. On the basis of this data, a fitting function is created. In a case where a plurality of rotary machine systems of the same type are operated in a factory or the like, data measured for one device can also be used for other systems. Therefore, this method is effective.

In fitting, only data in a specific range may be selected, whereby accuracy of the fitting can be improved. For example, regarding the belt tension, the feature quantity increases from a normal state, on the belt loosening side and the belt strained side with respect to the proper tension. Therefore, by extracting only data in a range on only one side, fitting can be performed with a monotonously increasing function. In the present embodiment, with loosening of the belt targeted, only data in a range smaller than the proper tension are extracted and fitting is performed.

Next, a method for function fitting will be described. In the function fitting, the kind of a function and the creation method therefor are not designated. Here, fitting is performed by a least squares method using a linear function. The function information storage unit 135f4 stores a fitted formula. The fitted linear function is represented by Formula (7).

$$y = kx + m \qquad ( 7 )$$

Here, k and m are coefficients for fitting, y is a feature quantity, and x is an abnormality degree. The function information storage unit 135f4 stores k and m.

Quantitative evaluation for the abnormality degree using the stored formula will be described. As in embodiment 1, the feature quantity C_{b} is calculated from current data during driving. Here, the calculated feature quantity C_{b} is referred to as a feature quantity y. The abnormality degree x at the feature quantity y is calculated by Formula (7) as follows.

$$x = ( y - m ) / k \qquad ( 8 )$$

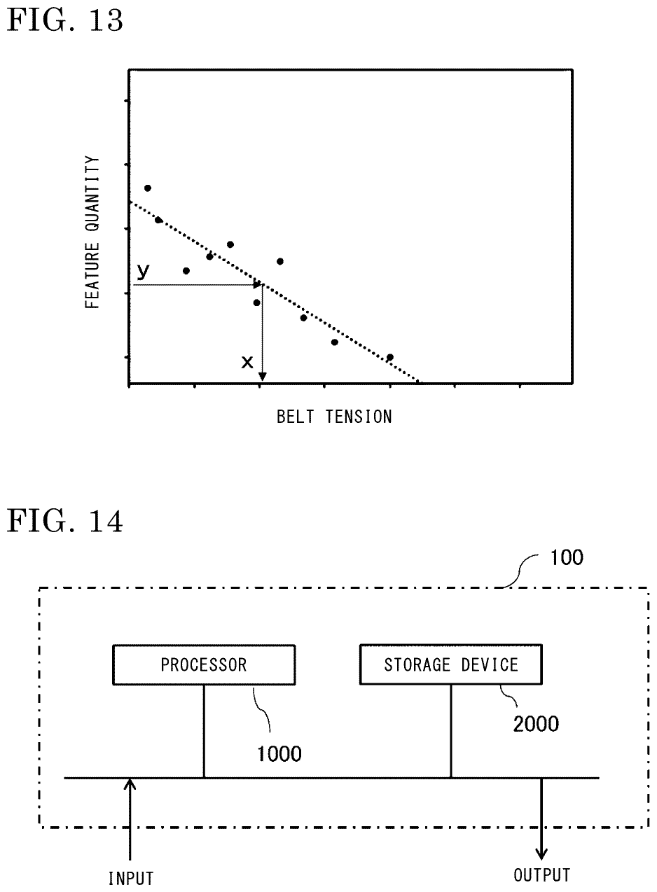

FIG. 13 shows the state of fitting of a linear function. In FIG. 13, the abnormality degree is the tension of the belt.

In the above case, a linear function is selected as an example of a function to be fitted. However, in order to improve accuracy, another function may be selected, or in acquiring the sum of the absolute values, components may be each weighted. In a case of performing fitting by a linear function with components each weighted, there is an advantage that the calculation amount in function fitting is reduced.

The calculated abnormality degree is stored in the abnormality degree storage unit 137 and is outputted to the output unit 140. In embodiment 1, an abnormality determination is outputted only when diagnosis as abnormality has been obtained. Also in embodiment 2, the abnormality degree may be outputted after a specific threshold is reached. That is, in the abnormality determination unit 135f of embodiment 1, the function information storage unit 135f4 and the abnormality degree calculation unit 135f5 may be further provided, and both of an abnormality determination and an abnormality degree may be outputted. An abnormality degree may be outputted irrespective of whether in a normal state or an abnormal state.

In the above description, the calculation method for the abnormality degree in abnormality diagnosis for the belt tension has been described. However, the abnormality degree can be calculated in the same manner also in another abnormality determination. For example, in abnormality diagnosis for the electric motor 5, the abnormality degree of eccentricity may be calculated.

In the above embodiments 1 and 2, the abnormality diagnosis device 100 includes a processor 1000 and a storage device 2000 as shown in a hardware example in FIG. 14. Although not shown, the storage device is provided with a volatile storage device such as a random access memory and a nonvolatile auxiliary storage device such as a flash memory. Instead of the flash memory, an auxiliary storage device of a hard disk may be provided. The processor 1000 executes a program inputted from the storage device 2000. In this case, the program is inputted from the auxiliary storage device to the processor 1000 via the volatile storage device. The processor 1000 may output data such as a calculation result to the volatile storage device of the storage device 2000 or may store such data into the auxiliary storage device via the volatile storage device.

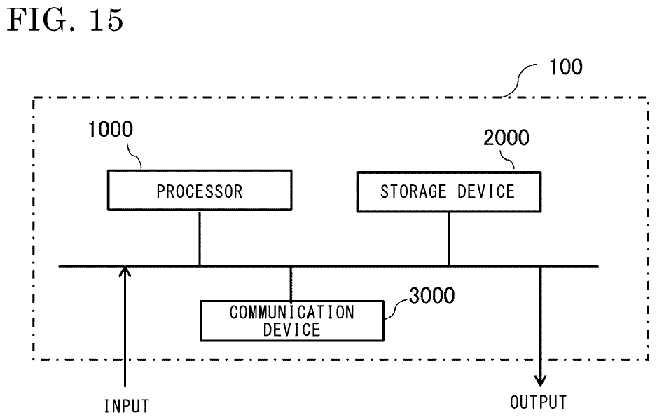

As shown in FIG. 15, the abnormality diagnosis device 100 may further include a communication device 3000. For example, in a case where a plant monitoring device for collectively monitoring the load apparatus 10 is provided in a plant where the load apparatus 10 is provided, an abnormality diagnosis result or an abnormality degree obtained by the abnormality diagnosis device 100 can be transmitted from the output unit 140 to the plant monitoring device.

Although it has been described that the abnormality diagnosis device 100 has the hardware configuration shown in FIG. 14 or FIG. 15, each of the electric motor control device 110 and the abnormality diagnosis unit 130 may have the hardware configuration shown in FIG. 14 or FIG. 15.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

2 power supply
5 electric motor
6 motive power transmission mechanism
61 belt
7 load equipment
10 load apparatus
100 abnormality diagnosis device
110 electric motor control device
111 inverter
112 control unit
120 current detector
130 abnormality diagnosis unit
131 load apparatus setting unit
132 first storage unit
133 second storage unit
133a determination reference storage unit
133b electric motor frequency storage unit
133c motive power transmission mechanism frequency storage unit
133d load equipment frequency storage unit
135 computation unit
135a spectrum analysis unit
135b sideband peak analysis unit
135c peak analysis unit
135d frequency determination unit
135f abnormality determination unit
135f1 load torque selection unit
135f2 feature quantity calculation unit
135f3 feature quantity determination unit
135f4 function information storage unit
135f5 abnormality degree calculation unit
136 diagnosis result storage unit
137 abnormality degree storage unit
140 output unit
1000 processor
2000 storage device
3000 communication device

1. An abnormality diagnosis device for determining abnormality of a load apparatus including an electric motor and load equipment connected to the electric motor, the abnormality diagnosis device comprising:
a current detector which detects current of the electric motor; and
an abnormality diagnosis circuitry to perform FFT analysis on the current detected by the current detector and determines abnormality using extracted spectrum peaks, wherein
the abnormality diagnosis circuitry includes
a peak analysis circuitry to perform analysis using a power supply frequency of the electric motor and frequencies of sideband peaks with respect to the power supply frequency, and analyzes the extracted spectrum peaks for each frequency,
a frequency determination circuitry to determine, from the spectrum peaks analyzed by the peak analysis circuitry, which kind of the electric motor and the load equipment the spectrum peak for each frequency is due to,
a frequency storage to store, for each load torque of the electric motor, the frequencies and signal intensities of the spectrum peaks due to the electric motor, and the frequencies and signal intensities of the spectrum peaks due to the load equipment, when the load apparatus is in a normal state, and
an abnormality determination circuitry, and
the abnormality determination circuitry includes
a load torque selection circuitry to select a load torque present when the current is detected by the current detector in abnormality diagnosis,
a feature quantity calculation circuitry to, with respect to a plurality of diagnosis spectrum peaks for which the kind has been determined from FFT analysis on the current detected in the abnormality diagnosis, read the frequencies and the signal intensities of the spectrum peaks in the normal state corresponding to the load torque selected by the load torque selection circuitry and the determined kind, from the frequency storage, and calculate, regarding the plurality of diagnosis spectrum peaks, absolute values of differences of signal intensities from those in the normal state for the respective frequencies, to use a sum of the absolute values as a feature quantity, and
a feature quantity determination circuitry to compare a predetermined threshold and the feature quantity to determine abnormality of the load apparatus,
wherein the abnormality diagnosis circuitry further comprises at least one processor configured to implement the peak analysis circuitry, the frequency determination circuitry, and the abnormality determination circuitry including the load torque selection circuitry, the feature quantity calculation circuitry and the feature quantity determination circuitry.

2. The abnormality diagnosis device according to claim 1, wherein
the load apparatus further includes a motive power transmission mechanism between the electric motor and the load equipment,
the frequency determination circuitry determines, from the spectrum peaks analyzed by the peak analysis circuitry, which kind of the electric motor, the motive power transmission mechanism, and the load equipment the spectrum peak for each frequency is due to, and
the frequency storage stores, for each load torque of the electric motor, the frequencies and the signal intensities of the spectrum peaks due to the electric motor, the frequencies and the signal intensities of the spectrum peaks due to the load equipment, and the frequencies and signal intensities of the spectrum peaks due to the motive power transmission mechanism, when the load apparatus is in the normal state.

3. The abnormality diagnosis device according to claim 2, wherein
the motive power transmission mechanism is a belt, and
the abnormality determination circuitry determines tension abnormality of the belt.

4. The abnormality diagnosis device according to claim 1, wherein
the feature quantity calculation circuitry, with spectrum peaks for different orders present as the plurality of diagnosis spectrum peaks, calculates the absolute values of the differences of the signal intensities from those in the normal state for the respective frequencies of the plurality of diagnosis spectrum peaks, to use the sum of the absolute values as the feature quantity.

5. The abnormality diagnosis device according to claim 1, wherein
the abnormality determination circuitry further includes a function information storage and an abnormality degree calculation circuitry to calculate an abnormality degree representing a degree of progress from the normal state to an abnormal state, fitting for a correlation between the abnormality degree and the feature quantity calculated by the feature quantity calculation circuitry is performed using a function stored in the function information storage, and the abnormality degree calculation circuitry calculates the abnormality degree corresponding to the feature quantity on the basis of the fitted function.

6. The abnormality diagnosis device according to claim 5, wherein
the function stored in the function information storage is a linear function.

7. The abnormality diagnosis device according to claim 1, wherein
the load torque of the electric motor is calculated on the basis of the current detected by the current detector.

8. An abnormality diagnosis device for determining abnormality of a load apparatus including an electric motor and load equipment connected to the electric motor, the abnormality diagnosis device comprising:
a current detector which detects current of the electric motor; and
an abnormality diagnosis circuitry to perform FFT analysis on the current detected by the current detector and determines abnormality using extracted spectrum peaks, wherein
the abnormality diagnosis circuitry includes
a peak analysis circuitry to perform analysis using a power supply frequency of the electric motor and frequencies of sideband peaks with respect to the power supply frequency, and analyzes the extracted spectrum peaks for each frequency,
a frequency determination circuitry to determine, from the spectrum peaks analyzed by the peak analysis circuitry, which kind of the electric motor and the load equipment the spectrum peak for each frequency is due to,
a frequency storage to store, for each load torque of the electric motor, the frequencies and signal intensities of the spectrum peaks due to the electric motor, and the frequencies and signal intensities of the spectrum peaks due to the load equipment, when the load apparatus is in a normal state, and
an abnormality determination circuitry, and
the abnormality determination circuitry includes
a load torque selection circuitry to select a load torque present when the current is detected by the current detector in abnormality diagnosis,
a feature quantity calculation circuitry to with respect to a plurality of diagnosis spectrum peaks for which the kind has been determined from FFT analysis on the current detected in the abnormality diagnosis, read the frequencies and the signal intensities of the spectrum peaks in the normal state corresponding to the load torque selected by the load torque selection circuitry and the determined kind, from the frequency storage unit, and calculate, regarding the plurality of diagnosis spectrum peaks, absolute values of differences of signal intensities from those in the normal state for the respective frequencies, to use a sum of the absolute values as a feature quantity,
a function information storage, and
an abnormality degree calculation circuitry to calculate an abnormality degree representing a degree of progress from the normal state to an abnormal state,
fitting for a correlation between the abnormality degree and the feature quantity calculated by the feature quantity calculation circuitry is performed using a function stored in the function information storage, and
the abnormality degree calculation circuitry calculates the abnormality degree corresponding to the feature quantity on the basis of the fitted function,
wherein the abnormality diagnosis circuitry further comprises at least one processor configured to implement the peak analysis circuitry, the frequency determination circuitry, and the abnormality determination circuitry including the load torque selection circuitry, the feature quantity calculation circuitry, the abnormality degree calculation circuitry.

9. The abnormality diagnosis device according to claim 8, wherein
the load apparatus further includes a motive power transmission mechanism between the electric motor and the load equipment,
the frequency determination circuitry determines, from the spectrum peaks analyzed by the peak analysis circuitry, which kind of the electric motor, the motive power transmission mechanism, and the load equipment the spectrum peak for each frequency is due to, and
the frequency storage stores, for each load torque of the electric motor, the frequencies and the signal intensities of the spectrum peaks due to the electric motor, the frequencies and the signal intensities of the spectrum peaks due to the load equipment, and the frequencies and signal intensities of the spectrum peaks due to the motive power transmission mechanism, when the load apparatus is in the normal state.

10. The abnormality diagnosis device according to claim 9, wherein
the motive power transmission mechanism is a belt, and
the abnormality determination circuitry determines tension abnormality of the belt.

11. The abnormality diagnosis device according to claim 8, wherein
the feature quantity calculation circuitry, with spectrum peaks for different orders present as the plurality of diagnosis spectrum peaks, calculates the absolute values of the differences of the signal intensities from those in the normal state for the respective frequencies of the plurality of diagnosis spectrum peaks, to use the sum of the absolute values as the feature quantity.

12. The abnormality diagnosis device according to claim 8, wherein
the function stored in the function information storage is a linear function.

13. An abnormality diagnosis method for determining abnormality of a load apparatus including an electric motor and load equipment connected to the electric motor, the abnormality diagnosis method comprising:
detecting current of the electric motor;
performing FFT analysis on the detected current and detecting spectrum peaks;
extracting frequencies of sideband peaks with respect to a power supply frequency of the electric motor, from the spectrum peaks detected in the performing FFT analysis;
determining which kind of the electric motor and the load equipment the spectrum peak for each frequency is due to, using the power supply frequency and the extracted frequencies of the sideband peaks;
selecting a load torque of the electric motor present when the current is detected;
with respect to signal intensities for the respective frequencies of a plurality of the spectrum peaks determined for each kind, calculating, as a feature quantity, a sum of absolute values of differences from signal intensities for the frequencies of the spectrum peaks due to the kind in a normal state corresponding to the determined kind and corresponding to the selected load torque; and
comparing the calculated feature quantity with a predetermined threshold and determining abnormality of the load apparatus.

14. The abnormality diagnosis method according to claim 13, wherein
the load apparatus further includes a motive power transmission mechanism between the electric motor and the load equipment, and
which kind of the electric motor, the motive power transmission mechanism, and the load equipment the spectrum peak for each frequency is due to, is determined, using the power supply frequency and the extracted frequencies of the sideband peaks.

15. The abnormality diagnosis method according to claim 14, wherein
the motive power transmission mechanism is a belt, and
tension abnormality of the belt is determined.

16. The abnormality diagnosis method according to claim 13, wherein
in calculating the feature quantity, with spectrum peaks for different orders present as the plurality of spectrum peaks, the absolute values of the differences of the signal intensities from those in the normal state are calculated for the respective frequencies of the plurality of spectrum peaks, and the sum of the absolute values is used as the feature quantity.

17. The abnormality diagnosis method according to claim 13, further comprising, after determining abnormality of the load apparatus, performing fitting for a relationship between the feature quantity and an abnormality degree using a predetermined function, and calculating the abnormality degree representing a degree of progress from the normal state to an abnormal state.

18. The abnormality diagnosis method according to claim 17, wherein
the function used in calculating the abnormality degree is a linear function.

19. The abnormality diagnosis method according to claim 13, wherein
the frequencies and the signal intensities of the spectrum peaks due to the kind in the normal state and the load torque are acquired and stored in advance.
